(19) United States
(12) Patent Application Publication
(10) Pub. No.: US 2005/0266594 A1
(43) Pub. Date: Dec. 1, 2005

(54) Manufacturing method for display device

(76) Inventors: Takuo Kaitoh, Mobara (JP); Takahiro Kamo, Chiba (JP); Hidekazu Miyake, Mobara (JP); Toshihiko Itoga, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/138,471

(22) Filed: May 27, 2005

(30) Foreign Application Priority Data
May 31, 2004 (JP) 2004-160617

(51) Int. Cl. H01L 21/84

(52) U.S. Cl. 438/30; 438/166

(57) ABSTRACT

A manufacturing method for a display device includes: a first thin film transistor that is formed in a first region over a substrate and has a first threshold value according to doping of a first impurity into a semiconductor layer in a channel region; and a second thin film transistor that is formed in a second region over the substrate and has a second threshold value, which is different from the first threshold value, according to doping of a second impurity into a semiconductor layer in a channel region, wherein a crystallized semiconductor layer, which is used in the channel region of the second thin film transistor, is obtained by subjecting a semiconductor layer in the second region to fusing treatment in a state in which the second impurity is applied over the semiconductor layer.

The present application claims priority from Japanese application JP2004-160617, filed on May 31, 2004, the content of which is hereby incorporated by reference into this application.

### BACKGROUND OF THE INVENTION

The present invention relates in general to a method of manufacture of a flat display device. In particular, the present invention is applicable to the manufacture of a display device in which a large number of thin film transistors having different operation characteristics are placed concurrently over a substrate.

Flat display devices of various systems have already been put to practical use or are the subject of research for practical use. The flat display devices include a display device that provides a high definition display and is capable of producing a color display for a notebook computer or a display monitor, a liquid crystal display device using a liquid crystal panel as a display panel for a cellular phone, an organic electroluminescence display device (an organic EL display device) using an electroluminescence (in particular, organic electroluminescence) element, and a field emission display device (FED) using a field emission element.

As a flat display device, a display device known as a system-in-panel has been developed. The system-in-panel is manufactured by directly building a display area, in which there are a large number of pixels constituted by thin film transistor circuits disposed in a matrix arrangement, and peripheral circuits (e.g., a scanning signal drive circuit and a video signal drive circuit for driving the pixels disposed around the display area and other peripheral circuits) in an insulating substrate of glass or the like. A transparent insulating substrate, in which various thin film transistors are built, is also referred to as a thin film transistor (TFT) substrate or an active matrix substrate. In the following explanation, the transparent insulating substrate will also be represented as a TFT substrate or simply as a substrate.

A large number of thin film transistor circuits are built on an identical substrate. For example, a pixel circuit forming a display area is built on an identical substrate constituting a flat display device and peripheral circuits (e.g., a scanning signal drive circuit, a video signal drive circuit, and other peripheral circuits) are built around the pixel circuit. In such a case, channel regions corresponding to the operation performance of the respective circuits are formed in a semiconductor layer on the identical substrate.

For forming the channel regions, a method has been proposed which involves forming a semiconductor layer in a portion, where thin film transistors of a circuit that is not required to operate at high speed is formed, as a normal polysilicon (p-Si) layer (having a relatively large particle diameter) (for example, formed by annealing, which uses an excimer laser(ELA), with an amorphous silicon (a-Si) layer or a particulate crystal polysilicon layer as a precursor) and selectively changing channel regions of a circuit required to operate at high speed to quasi-single crystals using a solid-state laser, a continuous-wave laser, or the like to form a quasi-single crystal silicon semiconductor layer. Note that, as will be described in detail later, the quasi-single crystal silicon semiconductor layer is a semiconductor layer in which crystals are grown to be relatively large crystals (e.g., crystals having a strip-like shape) compared with the usual polysilicon crystals that are so-called granular crystals, although not so large as single crystals.

Conventional techniques concerning such a quasi-single crystal are disclosed in, for example, JP-A-2002-222959 and JP-A-2003-124136.

### SUMMARY OF THE INVENTION

However, when a first circuit having thin film transistors, in which the usual polysilicon semiconductor layer is used as a channel region, and a second circuit having thin film transistors, in which the quasi-single crystal semiconductor layer is used as a channel region, are formed on a common substrate, it is necessary to control the operation characteristics (mainly threshold voltages of the thin film transistors) of both the circuits, respectively. For control of the threshold voltages, a method of injecting a so-called dopant into the semiconductor layers in the channel regions of the thin film transistors with ion implantation is generally used. It is possible to control the threshold voltages of the respective thin film transistors so that they are different by applying a predetermined amount of ion implantation to a predetermined region in combination with a technique for forming a mask in a photolithography step (an etching method using exposure and etching treatment).

However, when a large number of thin film transistors with different characteristics (threshold values) are built in a silicon semiconductor layer on a common substrate, the photolithography steps and ion implantation steps increase significantly compared with the case in which thin film transistors with the same characteristic are built in. Thus, the equipment and time required for manufacture increase and the so-called throughput decreases.

For example, a thin film transistor of a single channel (n-type or p-type) will be considered. When it is desired to vary a threshold value of a thin film transistor, which uses the usual polysilicon, in a pixel, and a threshold value of a thin film transistor, which uses quasi-single crystals, in a drive circuit, one of the thin film transistors (e.g., the thin film transistor in the pixel) is masked by the photolithography step and the ion implantation is applied to a channel region of the thin film transistor using the quasi-single crystals.

In the case of a thin film transistor of a Complementary Metal Insulator Semiconductor (C-MIS) type (note that, in this specification, MIS is used as a concept including MOS), since thin film transistors of the n-type and p-type are mixed, the photolithography step and the ion implantation step are required to vary the threshold values between these thin film transistors.

It is an object of the present invention to provide a manufacturing method with which it is possible to obtain a display device having thin film transistor circuits with different characteristics without increasing the number of steps needed for the manufacture thereof.

Characteristic points of the invention are as described below.

(a) Laser irradiation is applied to a semiconductor film with a dopant applied over the semiconductor film to polycrystallize the semiconductor film.

(b) When a precursor film is fused by the laser irradiation, the applied dopant is absorbed into the film. In addition, it is possible to activate the film simultaneously with crystallizing of the film. It is possible to attain almost 100% of an activation ratio.

(c) The dopant is absorbed into the film only in portions to which the laser irradiation is applied. Thus, by selectively crystallizing only necessary regions, rather than an entire substrate, without using a mask formed in the photolithography step, it is possible to obtain the same effect as the method of applying ion implantation only to necessary portions using the photolithographic process.

(d) It is possible to remove the dopant, which remains in the applied state in portions that are not crystallized, with cleaning. Thin film transistors arranged in the other region are not affected.

(e) It is possible to cope with both the single channel thin film transistor and the C-MIS thin film transistor.

Specific examples of constitutions of the manufacturing method for a display device according to the invention are as described below.

(1) A method of manufacture of a display device including: a first thin film transistor that is formed in a first region over a substrate and has a first threshold value according to doping of a first impurity into a semiconductor layer in a channel region; and a second thin film transistor that is formed in a second region over the substrate and has a second threshold value different from the first threshold value according to doping of a second impurity into a semiconductor layer in a channel region, wherein a crystallized semiconductor layer, which is used in the channel region of the second thin film transistor, is obtained by subjecting a semiconductor layer in the second region to fusing treatment in a state in which the second impurity is applied over the semiconductor layer.

(2) In the manufacturing method according to Example (1), the size of a crystal in the semiconductor layer used in the channel region of the second thin film transistor is larger than a size of the crystal in the semiconductor layer used in the channel region of the first thin film transistor.

(3) In the manufacturing method according to Examples (1) or (2), the fusing treatment for the semiconductor layer in the second region is performed by moving a continuous-wave laser relatively to the semiconductor layer while irradiating a laser beam on the semiconductor layer.

(4) In the manufacturing method according to any one of Examples (1) to (3), the semiconductor layer in the first region and the second region is subjected to the fusing treatment to modify the semiconductor layer to a crystallized semiconductor layer before applying the second impurity to the semiconductor layer.

(5) In the manufacturing method according to any one of Examples (1) to (4), the conductivity type of the first thin film transistor and the conductivity type of the second thin film transistor are the same.

(6) In the manufacturing method according to any one of Examples (1) to (4), the conductivity type of the first thin film transistor and the conductivity type of the second thin film transistor are different.

(7) A method of manufacture of a display device including: a first thin film transistor that is formed in a first region over a substrate and has a first threshold value according to doping of a first impurity into a semiconductor layer in a channel region; and a second thin film transistor that is formed in a second region over the substrate and has a second threshold value different from the first threshold value according to doping of a second impurity into a semiconductor layer in a channel region, wherein a crystallized semiconductor layer, which is used in the channel region of the first thin film transistor, is obtained by subjecting a semiconductor layer in the first region to fusing treatment in a state in which the first impurity is applied over the semiconductor layer, and a crystallized semiconductor layer, which is used in the channel region of the second thin film transistor, is obtained by subjecting a semiconductor layer in the second region to fusing treatment in a state in which the second impurity is applied over the semiconductor layer.

(8) In the manufacturing method according to Example (7), the semiconductor layer of the first thin film transistor and the semiconductor layer of the second thin film transistor have strip-like crystals.

(9) In the manufacturing method according to Examples (7) or (8), the fusing treatment for the semiconductor layer in the first region and the fusing treatment for the semiconductor layer in the second region are performed by moving a continuous-wave laser relatively to the semiconductor layer while irradiating a laser beam on the semiconductor layer.

(10) In the manufacturing method according to any one of Examples (7) to (9), the conductivity type of the first thin film transistor and the conductivity type of the second thin film transistor are the same.

(11) In the manufacturing method according to any one of Examples (7) to (9), the conductivity type of the first thin film transistor and the conductivity type of the second thin film transistor are different.

(12) A method of manufacture of a display device including: a first thin film transistor that is formed in a first region over a substrate and has a first threshold value according to doping of a first impurity into a semiconductor layer in a channel region; and a second thin film transistor that is formed in a second region over the substrate and has a second threshold value different from the first threshold value according to doping of a second impurity into a semiconductor layer in a channel region, wherein a crystallized semiconductor layer, which is used in the channel region of the first thin film transistor, is obtained by subjecting a semiconductor layer in the first region and the second region to fusing treatment in a state in which the first impurity is applied over the semiconductor layer, and a crystallized semiconductor layer, which is used in the channel region of the second thin film transistor, is obtained by subjecting the semiconductor layer in the second region to fusing treatment in a state in which the second impurity is applied over the semiconductor layer.

(13) In the manufacturing method according to Example (12), the size of a crystal in the semiconductor layer used in the channel region of the second thin film transistor is larger than the size of a crystal in the semiconductor layer used in the channel region of the first thin film transistor.

(14) In the manufacturing method according to Examples (12) or (13), the fusing treatment for the semiconductor layer in the second region is performed by moving a continuous-wave laser relatively to the semiconductor layer while irradiating a laser beam on the semiconductor layer.

(15) In the manufacturing method according to any one of Examples (12) to (14), the fusing treatment for the semiconductor layer in the first region and the second region in a state in which the first impurity is applied over the semiconductor layer is performed by irradiating an excimer laser beam or a solid-state laser beam on the semiconductor layer.

(16) In the manufacturing method according to any one of Examples (12) to (15), the conductivity type of the first thin film transistor and the conductivity type of the second thin film transistor are the same.

(17) In the manufacturing method according to any one of Examples (12) to (15), the conductivity type of the first thin film transistor and the conductivity type of the second thin film transistor are different.

Note that the first impurity and the second impurity may be different impurities, or they may be the same impurities having different concentrations.

As the fusing treatment in accordance with the invention, it is preferable to use laser annealing for irradiating a laser beam on a semiconductor layer constituting a precursor to fuse the semiconductor layer and, thereafter, crystallizing the semiconductor layer when the semiconductor layer cools to harden. It is possible to employ a technique of quasi-single crystallization in which a semiconductor layer constituting a precursor is modified to a layer of larger crystal grains by crystallization when the semiconductor layer is an amorphous silicon semiconductor layer or by recrystallization when the semiconductor layer is a microcrystal polysilicon semiconductor layer.

As a specific method for quasi-single crystallization, it is preferable to use Selectively Enlarging Laser Crystallization (SELAX) for scanning a required region of a silicon semiconductor layer with a laser to grow silicon crystals in the silicon semiconductor layer into strip-like silicon crystals of a relatively large size in a direction substantially parallel to the direction of the scanning. It is preferable that the semiconductor layer of strip-like silicon crystals (quasi-single crystals) formed by this method is arranged such that a crystal structure, in which a channel current crosses a grain boundary of the crystals extremely rarely, is obtained, that is, the longitudinal direction of the strip-like crystals is substantially parallel to the channel length direction (a direction connecting a source and a drain, i.e., a direction in which an electric current flows) when a thin film transistor is built in with the silicon semiconductor layer as a channel region. In this case, a crystallized semiconductor layer that is extremely similar to a single crystal semiconductor layer is formed in the channel region.

Note that the invention is not limited to these structures and can be changed appropriately within a range not departing from the technical concept of the invention.

According to the invention, since only a predetermined region on a substrate is selectively subjected to fusing treatment and is crystallized in a state in which a dopant is applied over a semiconductor film, the dopant is absorbed into only the predetermined region and a threshold value is controlled and the dopant is not absorbed into the other region. Thus, it is possible to delete the photolithography step and the ion implantation step and improve the throughput.

According to the invention, even if a number of a threshold value increases, it is possible to cope with the increase by repeating application of impurities, crystallization, and cleaning. Therefore, it is possible to significantly control an increase in the number of steps of the photolithography process and the ion implantation process and improve the throughput.

### BRIEF DESCRIPTION OF THE DRAWINGS

In the accompanying drawings:

FIGS. 1A to 1T are process diagrams showing a sequence of steps in the process of manufacture of a C-MIS thin film transistor, which represents a first embodiment of the invention;

FIGS. 2A to 2B are process diagrams showing steps in a method of manufacture of a display device of the invention in comparison with a manufacturing method of a comparative example;

FIGS. 3A to 3M are process diagrams showing a sequence of the steps in the process of manufacture of a single channel thin film transistor, which represents a second embodiment of the invention;

FIG. 4 is a diagram of a thin film transistor substrate constituting the display device of the invention;

FIG. 5 is a diagram showing a layout of thin film transistors that are formed in circuit sections that are required to operate at high speed;

FIG. 6 is a plan view illustrating a quasi-single crystallization technique;

FIG. 7 is a plan view illustrating a state in which quasi-single crystallization is performed;

FIG. 8 is a plan view illustrating a state in which quasi-single crystals are etched in an island shape; and

FIG. 9 is a diagram showing an example of a thin film transistor using quasi-single crystals.

### DETAILED DESCRIPTION OF THE INVENTION

Embodiments of the invention will be explained hereinafter in detail with reference to the accompanying drawings. In the following explanation, an insulating substrate forming a semiconductor layer is assumed to be a glass substrate.

### First Embodiment

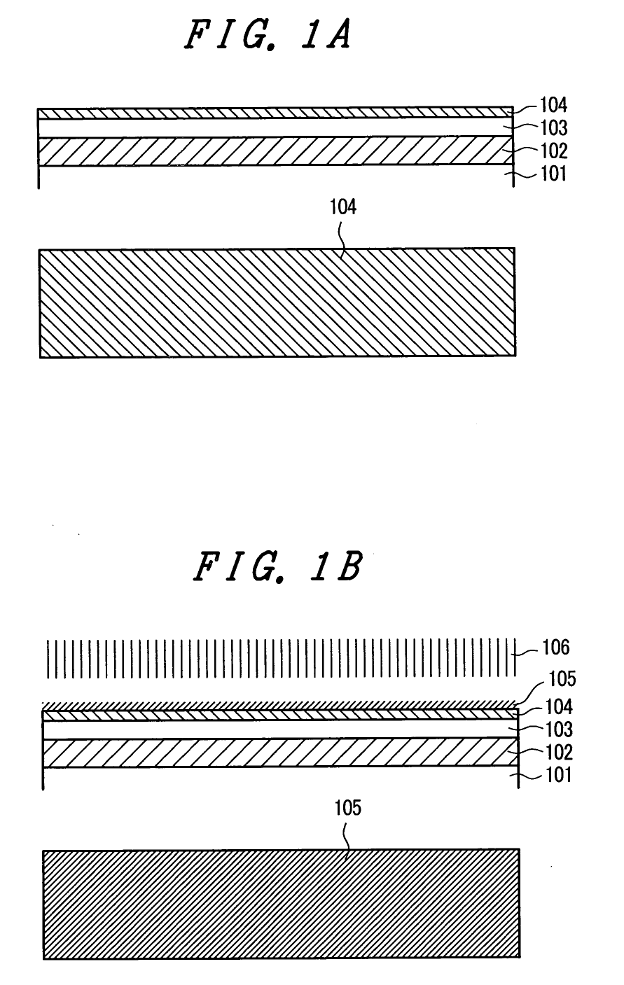

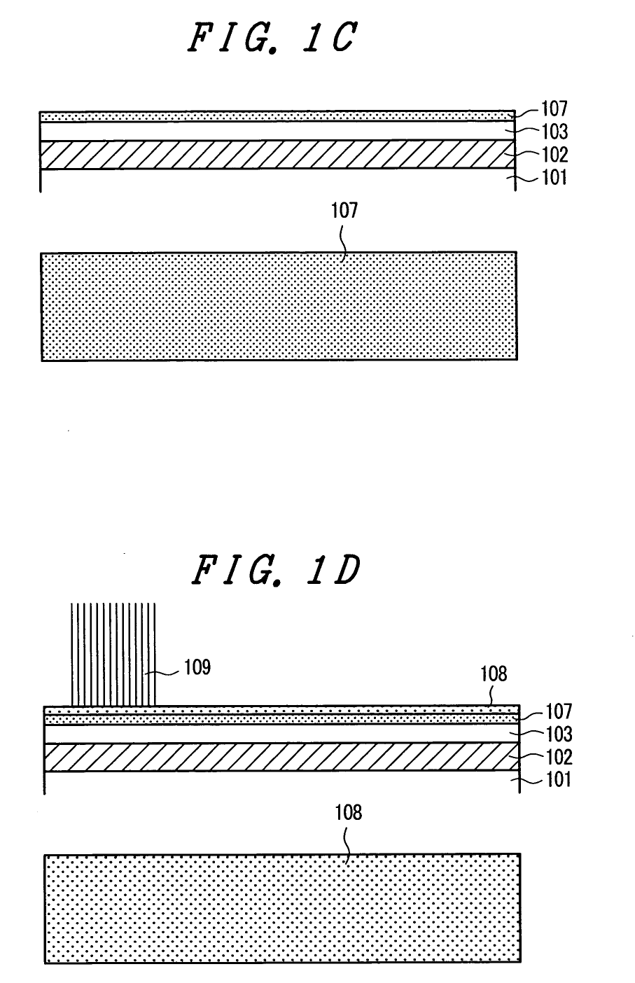

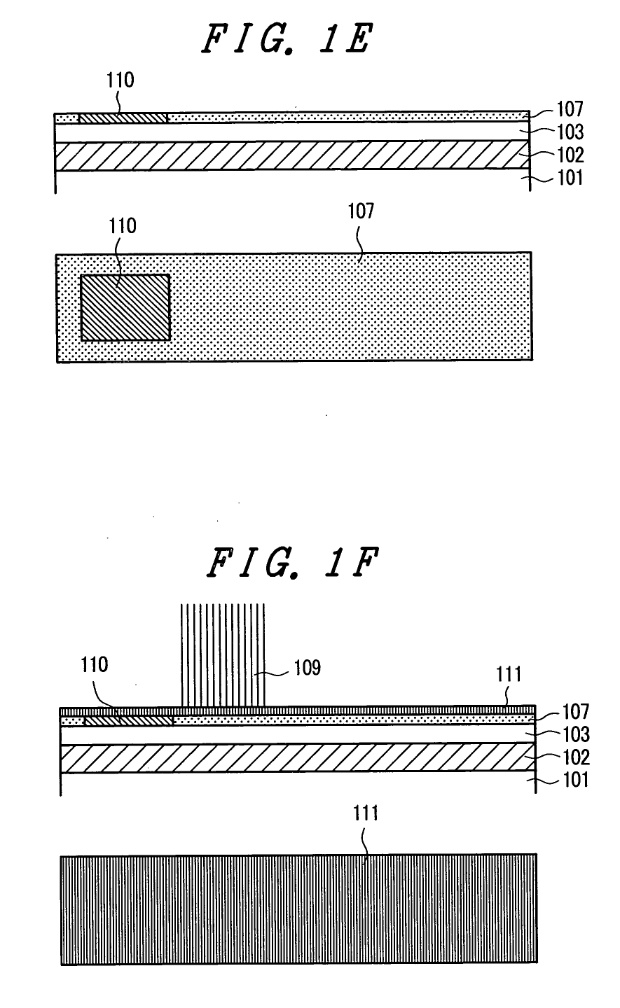

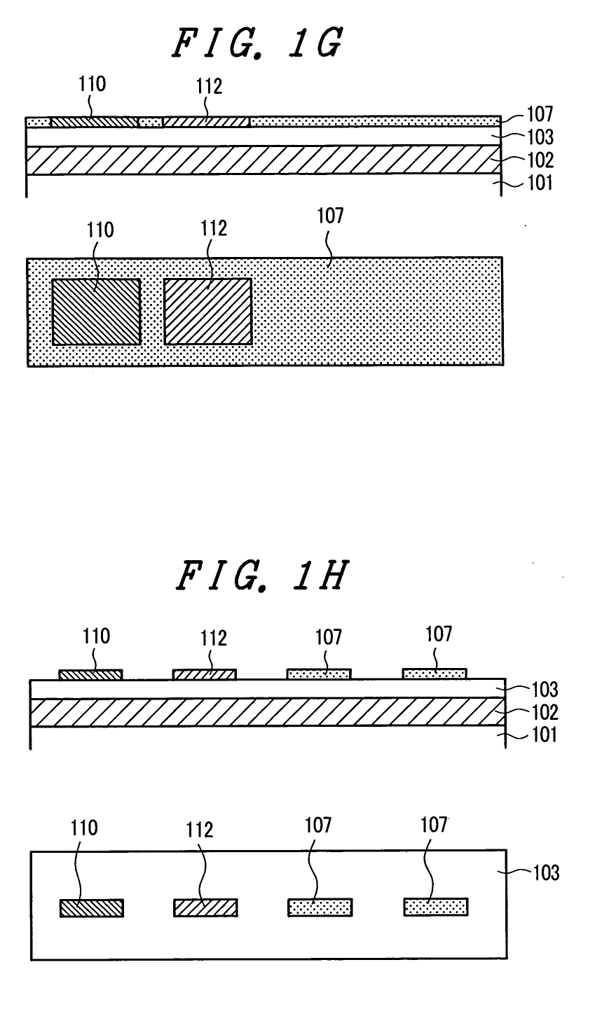

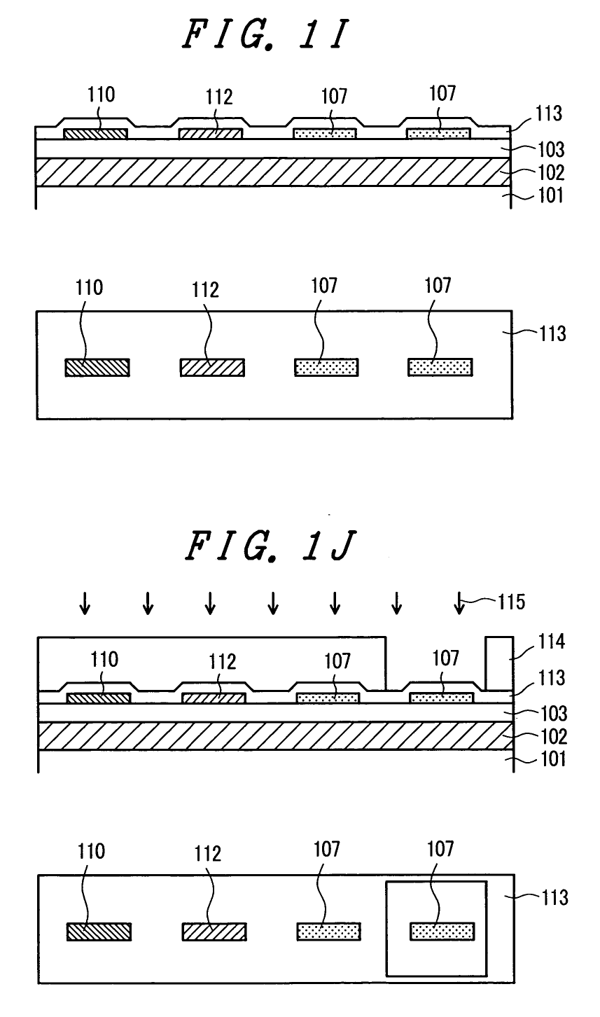

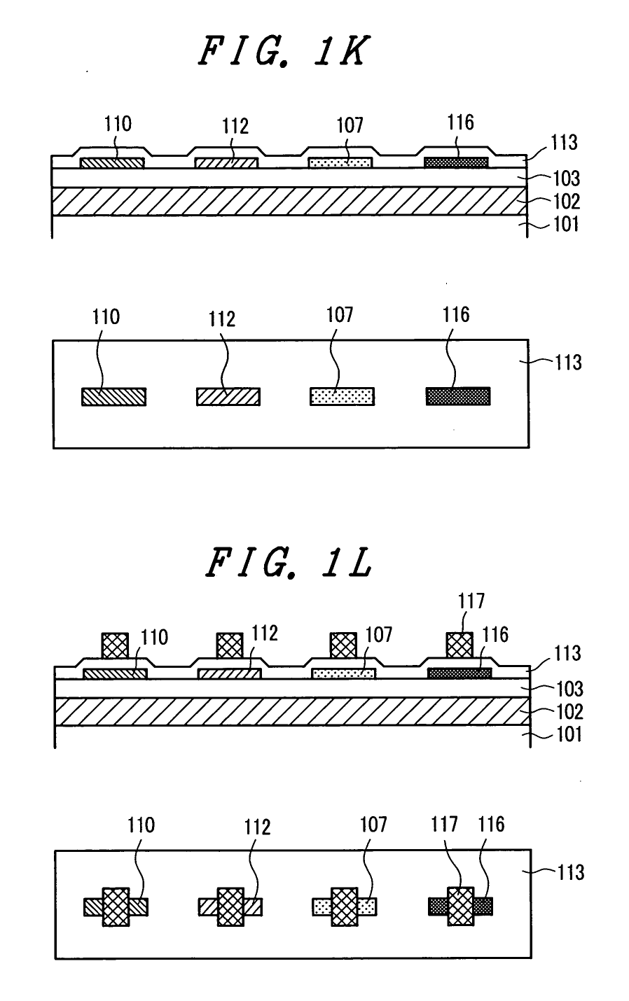

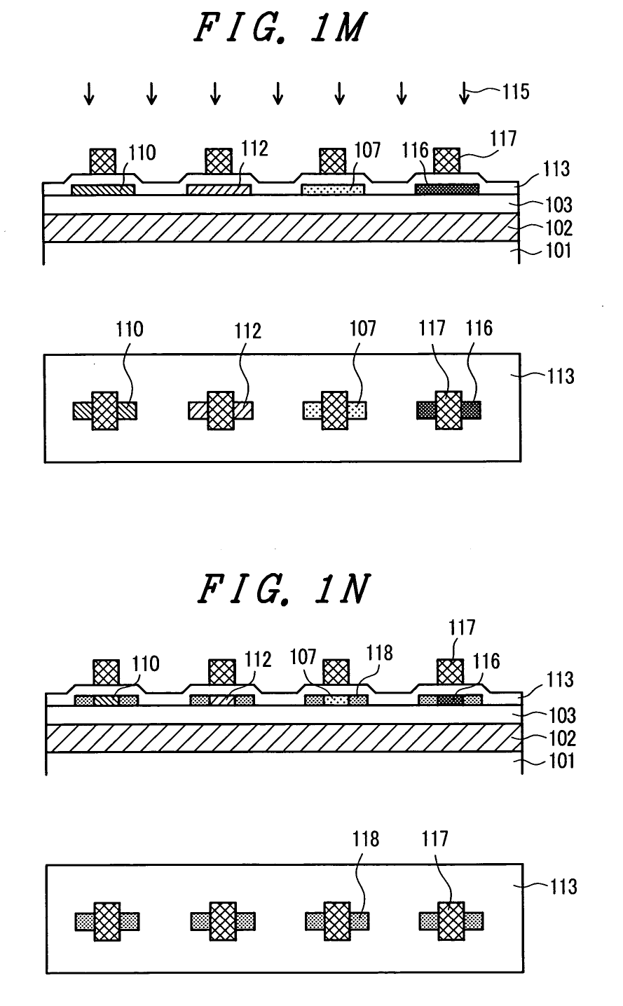

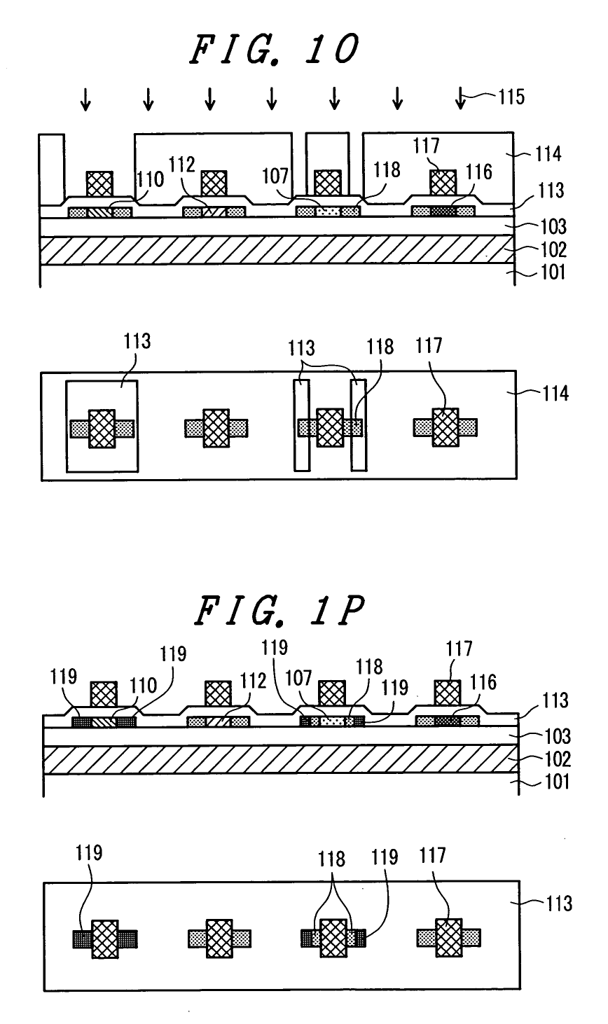

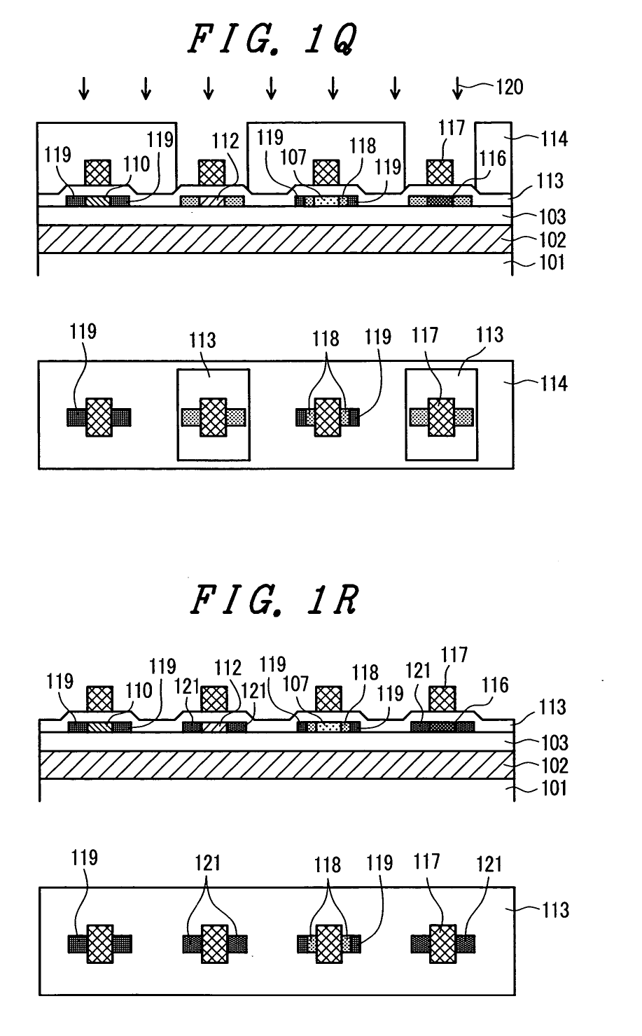

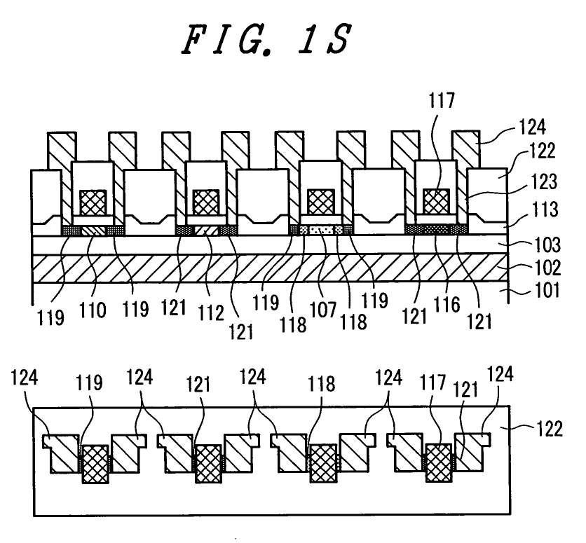

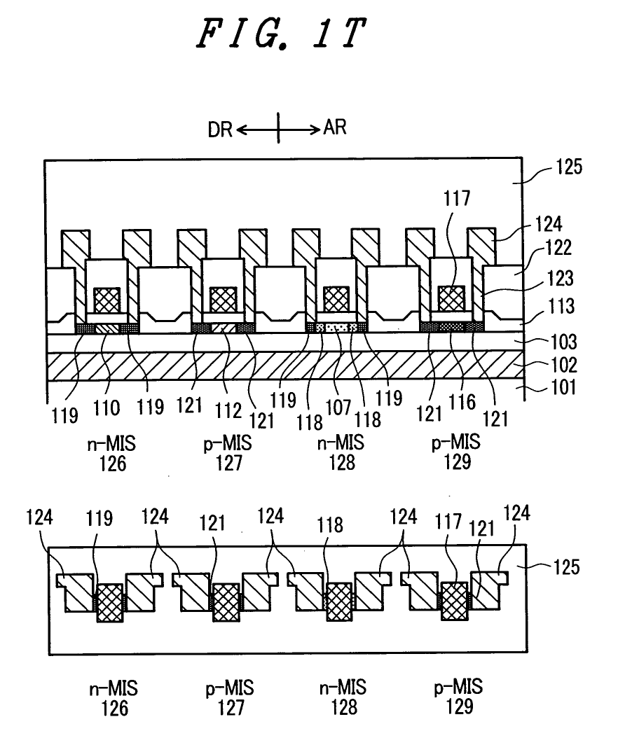

FIGS. 1A to 1T are process diagrams showing a sequence of manufacturing steps for fabrication of a C-MIS thin film transistor, which represents a first embodiment of the invention. In each of the figures, the upper half of the figure is a sectional view cut along a surface perpendicular to a glass substrate, and the lower half of the figure is a plan view parallel to the glass substrate. The manufacturing process will be explained with reference to FIGS. 1A to 1T in the order of the steps thereof.

In FIG. 1A, an SiN layer 102 and an SiO₂ layer 103 are formed on a glass substrate 101 as base layers. An amorphous silicon (a-Si) film 104 is formed on the base layers by the plasma CVD method. The base layers and the a-Si film 104 are subjected to thermal treatment to remove hydrogen in the a-Si film 104.

In FIG. 1B, a dopant 105 for controlling a threshold value (Vth) of an “n-type thin film transistor (TFT) using a polysilicon (p-Si) semiconductor film” is applied on the a-Si film 104.

In FIG. 1C, after applying the dopant 105, a laser beam 106 of an excimer laser or a solid-state laser are irradiated on the a-Si film 104 to modify the a-Si film 104 to a p-Si film 107 (crystallization). In this case, an incorporation of the dopant 105 together with the crystallization is performed.

In FIG. 1D, after applying a dopant 108 for controlling a threshold value (Vth) of an “n-type thin film transistor (n-TFT) using a quasi-single crystal semiconductor film” on the p-Si film 107, a laser beam 109 is irradiated on the p-Si film 107 from a solid-state laser or the like to anneal the p-Si film 107 and subject a required region of the p-Si film 107 to quasi-single crystallization. The region subjected to quasi-single crystallization is limited to a required region, such as a drive circuit section, where an n-type thin film transistor (n-TFT) using a quasi-single crystal silicon semiconductor film (qp-Si) is built in. It is desirable to use a continuous-wave laser beam as the laser beam 109.

In FIG. 1E, the p-Si film 107 in the required region is changed to a quasi-single crystal silicon semiconductor film (qp-Si film) 110 containing the dopant 108 by the treatment for irradiating the laser bream 109 in the step shown in FIG. 1 D. After irradiating the laser beam 109, the surface of the qp-Si film 110 is cleaned to remove the remaining dopant. Consequently, the dopant 108 is absorbed into only the region on which the laser beam 109 has been irradiated and the dopant 108 is not absorbed into the other region. Thus, it is possible to set different threshold values in the regions.

In FIG. 1F, a dopant 111 for controlling a threshold value (Vth) of a “p-type thin film transistor (p-TFT) using a quasi-single crystal semiconductor film” is applied on the p-Si film 107. After applying the dopant 111, the laser beam 109 is irradiated on the p-Si film 107 to anneal the p-Si film 107 and subject another required region of the p-Si film 107, which is different from the required region described above, to quasi-single crystallization. The region subjected to the quasi-single crystallization is limited to a required region where a p-type thin film transistor (p-TFT) using a quasi-single crystal silicon semiconductor film (qp-Si) is built in.

In FIG. 1G, the p-Si film 107 in the required region is changed to a quasi-single crystal silicon semiconductor film (qp-Si film) 112 containing the dopant 111 by the treatment for irradiating the laser beam 109 in the step shown in FIG. 1F. After irradiating the laser beam 109, the surface of the qp-Si film 112 is cleaned to remove the remaining dopant. The dopant 111 is absorbed into only the region of the quasi-single crystal silicon semiconductor film (qp-Si film) 112 that is formed by irradiating the laser beam 109 in the step shown in FIG. 1F. The p-Si film 107 in the other region is not affected. Thus, it is possible to set different threshold values in the regions.

In FIG. 1H, the qp-Si film 110 and the qp-Si film 112, and the p-Si films 107 obtained by applying laser annealing to required regions are treated in a photolithography step to be processed into the qp-Si film 110, the qp-Si film 112, and the p-Si films 107 in an island shape of a required size, respectively.

In FIG. 1I, a gate insulating film 113 is formed by the plasma CVD method to cover the qp-Si film 110, the qp-Si film 112, and the p-Si films 107 formed in the island shape. In a plan view of FIG. 1I, the respective islands of the qp-Si film 110, the qp-Si film 112, and the p-Si films 107 are shown in a transparent state. In plan views referred to below, the upper layers are shown in a transparent state.

In FIG. 1J, in order to give different threshold voltages to the p-Si films 107 when the thin film transistors are built in, the islands are covered by a photoresist 114, excluding the island of the p-Si film 107 (the island on the right side as seen in FIG. 1J) that requires ion implantation. Low concentration P⁺ ions 115 are implanted as a dopant for controlling a threshold value (Vth).

In FIG. 1K, after the ion implantation of the P⁺ ions 115, the photoresist 114 is removed. As a result, the island on the right side of the semiconductor films of the two p-Si films 107 shown in FIG. 1J is changed to a region 116 corresponding to a thin film transistor having a threshold voltage different from that of the island on the left side.

In FIG. 1L, a metal layer, which changes to a gate wiring and a storage capacitance line, is formed. The metal layer is etched in a photolithographic etching process to form gate metal layers 117 corresponding to the respective islands of the semiconductor films.

In FIG. 1M, in order to form Lightly Doped Drain (LDD) regions, the low concentration P⁺ ions 115 are implanted using the gate metal layers 117 as masks.

In FIG. 1N, the P⁺ ions 115 are doped only in a region not masked by the gate metal layers 117 to form LDD regions 118.

The LDD regions 118 are also referred to as n⁻ regions because the LDD regions 118 are low concentration n-type impurity regions.

In FIG. 10, after the ion implantation of the low concentration P⁺ ions 115, the photoresist 114 is applied on the islands excluding islands in required regions (in FIG. 10, the island at the left end and the second island from the right) to implant high concentration P⁺ ions 115. Note that, in the second island from the right, portions left as the LDD regions 118 are also covered by the photoresist 114.

Note that the gate metal layers 117 and the LDD regions 118 should be hidden by the photoresist 114, as seen in a plan view, so that the gate metal layers 117 and the LDD regions 118 are shown in a transparent state here.

In FIG. 1P, as a result of the ion implantation carried out in the step shown in FIG. 10, n⁺ regions 119 are formed in the island at the left end and the second island from the right.

In FIG. 1Q, the photoresist 114 is applied on the islands excluding the second island from the left and the island at the right end to implant high concentration B⁺ ions 120.

In FIG. 1R, after implanting the high concentration B⁺ ions 120, the photoresist 114 is removed to form p⁺ regions 121 in the second island from the left and the island at the right end. The p⁺ regions 121 change to source/drain regions of the p-MIS-TFT.

In FIG. 1S, an interlayer insulating film 122 is formed to perform annealing treatment for activation of the implanted impurities. Next, contact holes 123 are etched in the interlayer insulating film 122 and the gate insulating film 113 by photolithographic etching to form source/drain wirings 124.

In FIG. 1T, a passivation layer 125 is formed to cover the source/drain wirings 124 to perform terminating treatment. Consequently, thin film transistors n-MIS 126, p-MIS 127, n-MIS 128, and p-MIS 129, which have different crystal structures and different channels and controlled threshold voltages, are completed on the identical substrate. For example, the thin film transistors n-MIS 126 and p-MIS 127, having a high performance, are arranged in a drive circuit region DR, and the thin film transistors n-MIS 128 and p-MIS 129 are arranged in a pixel circuit region AR.

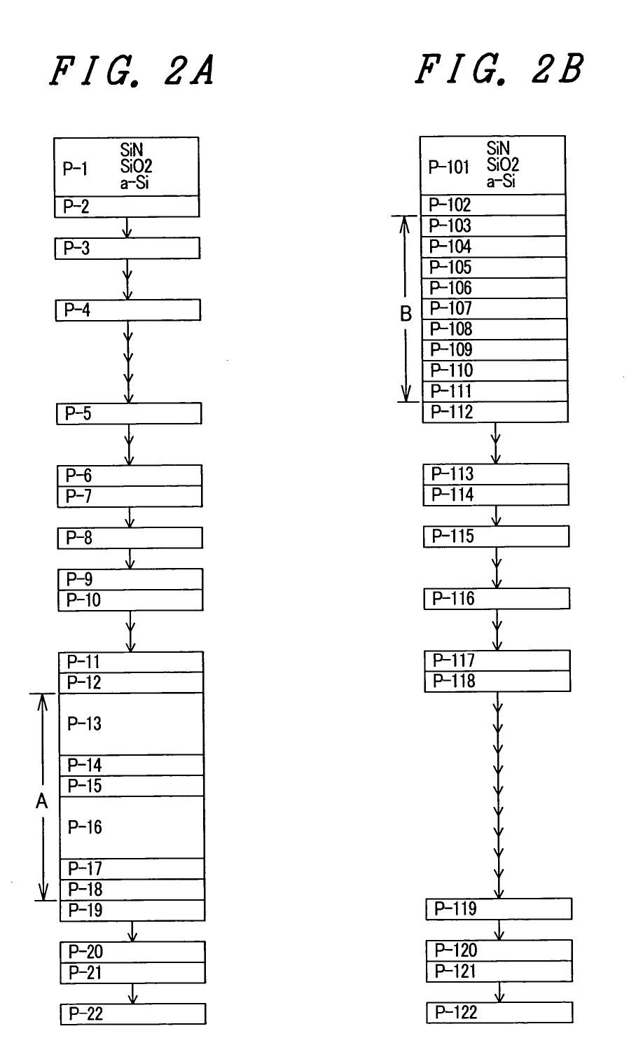

FIGS. 2A and 2B are process diagrams showing a comparison between the manufacturing method for a display device in accordance with the invention and a manufacturing method of a comparative example. FIG. 2A is a process diagram of the manufacturing method for a display device according to the comparative example. FIG. 2B is a process diagram of the manufacturing method for a display device according to the present invention. First, the manufacturing process of the comparative example shown in FIG. 2A will be explained. Note that, in the following explanation, steps of the manufacturing process are represented as, for example, “P-1”.

A silicon nitride SiN film and a silicon oxide SiO₂ film are formed on a surface of a glass substrate as base layers. An amorphous silicon (a-Si) layer is formed on the base layers (P-1 (three-layer deposition)). Thereafter, the layers are subjected to dehydrogenation treatment (P-2 (dehydrogenation)).

Excimer laser annealing (ELA) for irradiating an excimer laser beam on the a-Si layer to crystallize the a-Si layer is performed (in this crystallization, the a-Si layer changes to a silicon semiconductor layer subjected to so-called granular crystallization (microcrystallization) (P-3 (ELA crystallization)).

A required region of the silicon semiconductor layer subjected to the ELA crystallization, for example, a region in which thin film transistors (n-MIS, p-MIS) of a video signal drive circuit are built, is subjected to a strip-like crystallization (quasi-single crystallization) using the SELAX method (P-4 (SELAX crystallization)).

A resist is applied on the semiconductor layer, baked, exposed, and developed (P-5 (a first photolithography step)). Next, the semiconductor layer is dry-etched (P-6 (dry etching) to remove the resist with an asher (P-7 (asher removal)). Consequently, the semiconductor layer is etched in an island shape.

After cleaning the semiconductor layer, a gate insulating film is deposited (P-8 (gate insulating film deposition). B⁺ ion implantation for controlling an n-MIS-TFT threshold value is performed (P-9 (first ion implantation) and resist is applied, baked, exposed, and developed (P-10 (second photolithography step). P⁺ ion implantation for controlling a p-MIS-TFT threshold value is performed (P-11 (second ion implantation) to remove the resist with an asher (P-12 (asher removal)).

Resist is applied, baked, exposed, and developed (P-13 (third photoresist step) and B⁺ ion implantation for controlling a threshold value of a quasi-single crystal n-MIS-TFT is performed (P-14 (third ion implantation), and then the resist is removed with an asher (P-15 (asher removal)). Resist is applied, baked, exposed, and developed (P-16 (fourth photolithography step) and P⁺ ion implantation for controlling a threshold value of a quasi-single crystal p-MIS-TFT is performed (P-17 (fourth ion implantation), and then the resist is removed with an asher (P-18 (asher removal)).

The semiconductor layer is cleaned (P-19 (cleaning before activation annealing)) and then subjected to activation annealing (P-20 (activation annealing)), cleaning before gate metal sputtering (P-21 (cleaning before gate metal sputtering), and gate metal sputtering (P-22 (gate metal sputtering)).

Next, with reference to FIG. 2B, a process for the manufacture of a display device according to the invention will be explained. Steps P-101 and P-102 are the same as steps P-1 and P-2 in FIG. 2A, respectively. Steps P-112 to P-118 are the same as steps P-5 to P-8 and P-10 to P-12 in FIG. 2A. And, steps P-119 to P-122 are the same as steps P-19 to P-22 in FIG. 2A.

In FIG. 2B, steps P-103 to P-111 indicated by “B” are provided between steps P-102 and P-112. After the dehydrogenation step P-102, a dopant (B⁺) for controlling a threshold value of an n-MIS thin film transistor is applied . . . P-103 (first dopant application). Next, crystallization by excimer laser annealing is performed . . . P-104 (ELA crystallization). The semiconductor layer is cleaned . . . P-105 (cleaning)). A dopant (B⁺) for controlling a threshold value of an n-MIS thin film transistor is applied on the semiconductor layer . . . P-106 (second dopant application). Only a portion, in which a quasi-single crystal n-MIS thin film transistor is built, is subjected to crystallization by the SELAX method . . . P-107 (SELAX crystallization). The semiconductor layer is cleaned . . . P-108 (cleaning)). A dopant (P+) for controlling a threshold value of a p-MIS thin film transistor is applied . . . P-109 (third dopant application). Only a portion, in which a quasi-single crystal p-MIS thin film transistor is built, is subjected to crystallization by the SELAX method . . . P-110 (SELAX crystallization). The semiconductor layer is cleaned . . . P-111 (cleaning). Then, the process shifts to step P-112 (first photolithography step).

Note that step P-104 in FIG. 2B corresponds to step P-3 in FIG. 2A. Step P-107 in FIG. 2B corresponds to step P-4 in FIG. 2A.

In accordance with the invention, as shown in FIG. 2B, steps P-103 to P-111 are provided, and, after the step of asher removal (P-118), the process shifts to cleaning before activation annealing (P-119). In other words, steps P-13 to P-18 indicated by “A” in FIG. 2A are deleted.

In addition, step P-9 in FIG. 2A is deleted.

In the manufacturing method of the comparative example, there are the two photolithography steps P-13 and P-16 and the two ion implantation steps P-14 and P-17. In other words, ion implantation steps require a mask for ion implantation in a channel in a region of a quasi-single crystal n-MIS thin film transistor and a mask for ion implantation in a channel in a region of a quasi-single crystal p-MIS thin film transistor. On the other hand, in accordance with the invention, it is possible to delete the respective photolithography steps and the respective ion implantation steps. Two dopant application steps P-106 and P-109 for controlling a threshold value of a thin film transistor are added. However, since the dopant application steps are simple and require only a short time compared with the photolithography steps and the ion implantation steps, it is possible to reduce the time required in the process as a whole. Note that an ion implantation step may be used instead of the dopant application step in step P-103.

### Second Embodiment

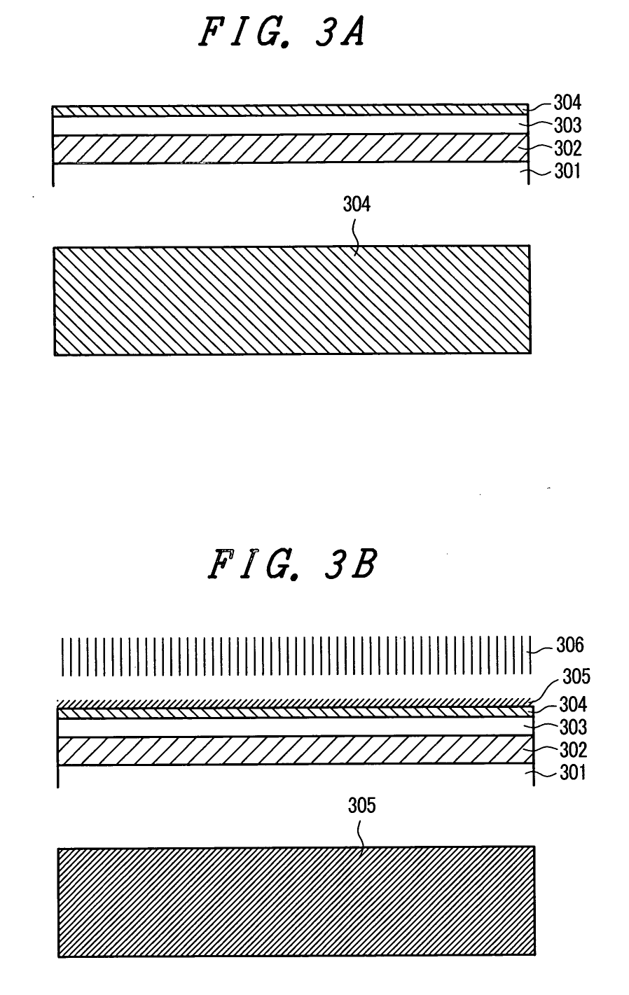

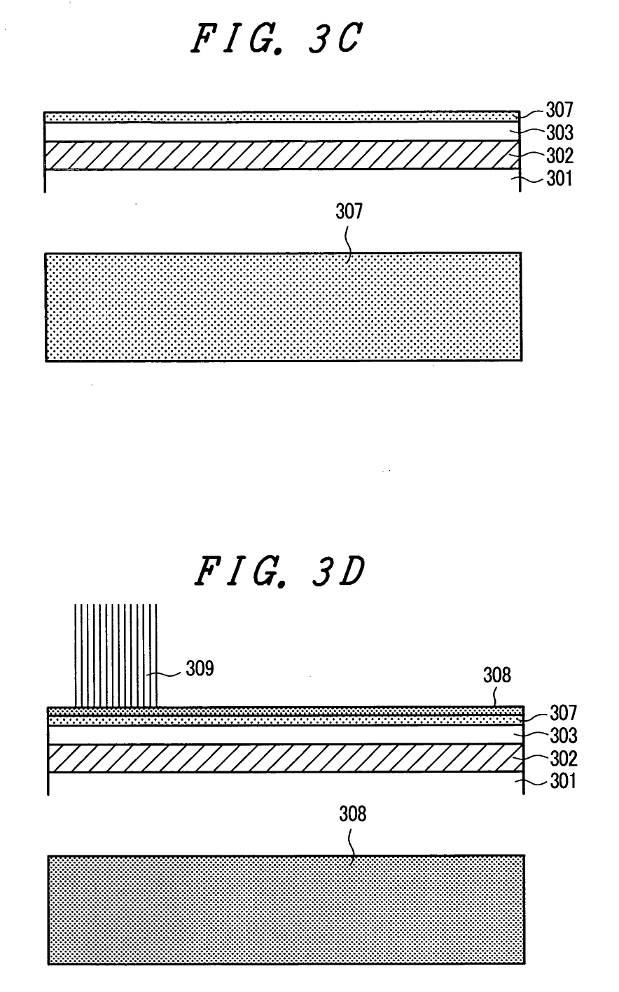

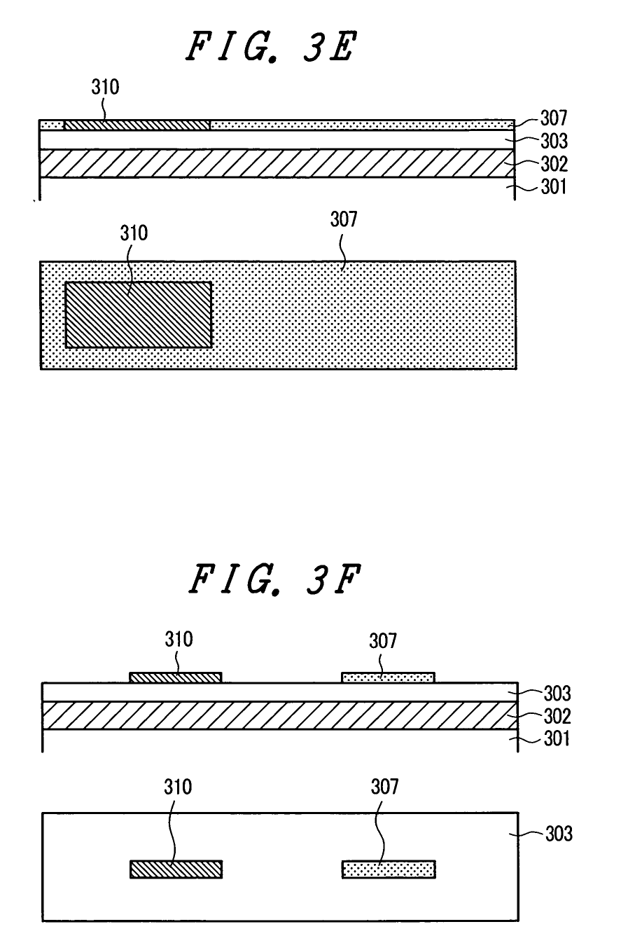

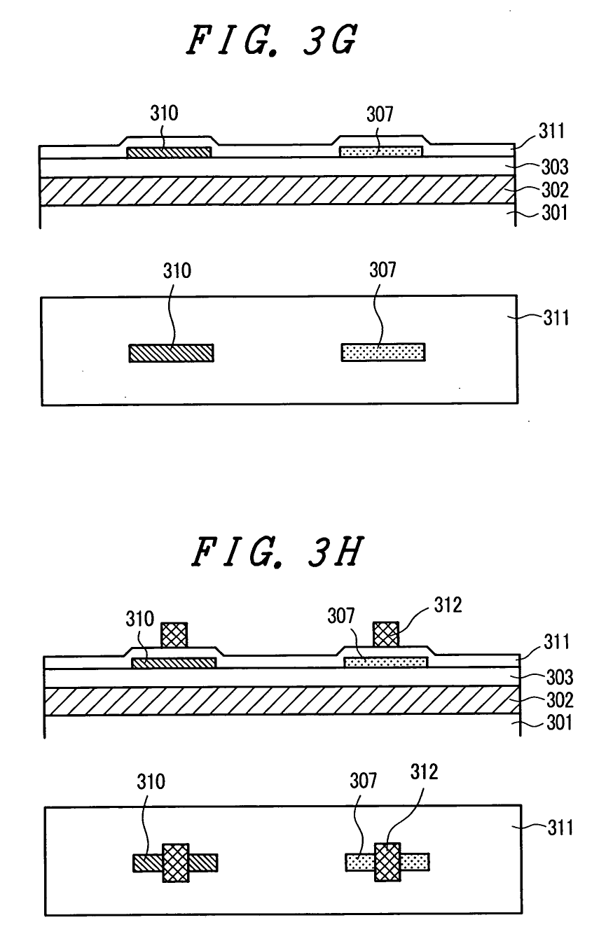

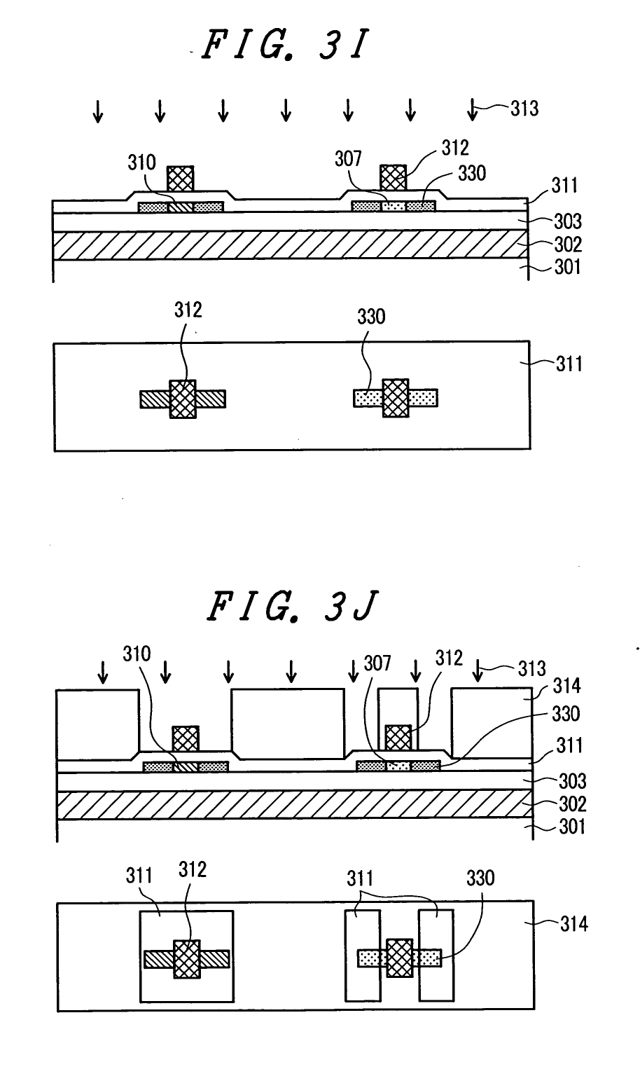

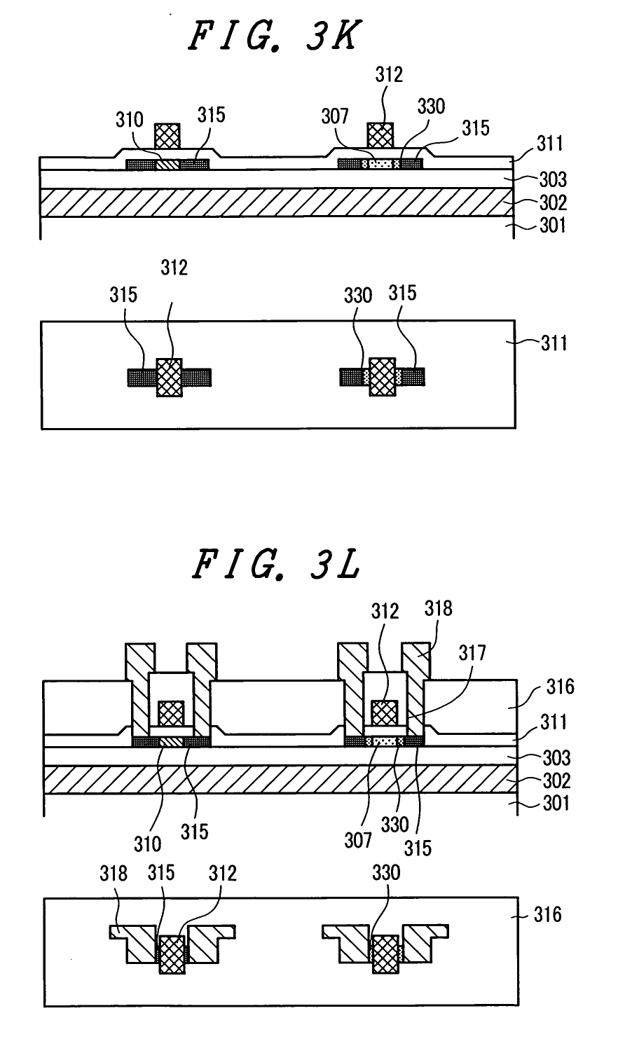

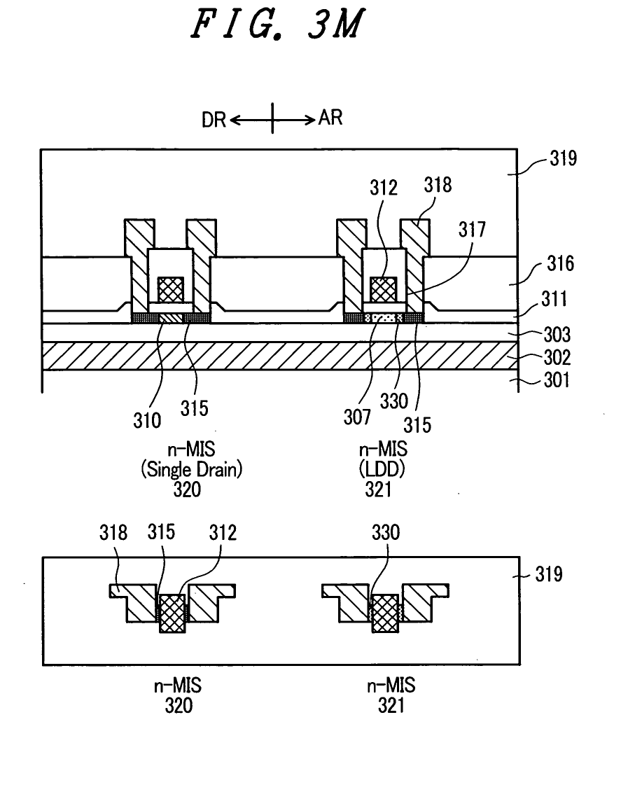

FIGS. 3A to 3M are process diagrams showing a sequence of steps in the process of fabrication of a single channel thin film transistor, which represents a second embodiment of the invention. In each of the figures, the upper half of the figure is a sectional view cut along a surface perpendicular to a glass substrate, and the lower half of the figure is a plan view parallel to the glass substrate. The manufacturing process will be explained hereinafter with reference to FIGS. 3A to 3M in the order of the steps shown thereof. Here, the manufacturing process will be explained with reference to an n-MIS-TFT as an example. However, the same holds true for a p-MIS-TFT. In that case, the dopant is changed as required or an LDD structure is changed to a single drain structure.

In FIG. 3A, an SiN layer 302 and an SiO₂ layer 303 are formed on a glass substrate 301 as base layers. An amorphous silicon (a-Si) film 304 is formed on the base layers by the plasma CVD method. The base layers and the a-Si film are subjected to thermal treatment to remove hydrogen in the a-Si film.

In FIG. 3B, a dopant 305 for controlling a threshold value (Vth) of an “n-type thin film transistor (TFT) using a polysilicon (p-Si) semiconductor film” is applied on the a-Si film 304. A laser beam 306 of an excimer laser or a solid-state laser is irradiated on the a-Si film 304 to modify the a-Si film 304 to a p-Si film 307 (FIG. 3C). In this case, the dopant 305 is absorbed into the p-Si film 307. Note that ion implantation may be used instead of a mask, because the mask is unnecessary in this step.

In FIG. 3D, after applying a dopant 308 for controlling a threshold value (Vth) of an “n-type thin film transistor (n-TFT) using a quasi-single crystal semiconductor film” on the p-Si film 307, a laser beam 309 is irradiated on a required region (to modify the region to a strip-like quasi-single crystal obtained by SELAX). In this case, the region, on which the laser beam 309 is irradiated, is limited to a portion in which an n-type thin film transistor using quasi-single crystals are built. For example, the region is a drive circuit region.

In FIG. 3E, the p-Si film 307 in the required region is changed to a quasi-single crystal silicon semiconductor film (qp-Si film) 310 containing the dopant 308 by the treatment for irradiating the laser beam 309 in the step shown in FIG. 3D. After irradiating the laser beam 309, the surface of the qp-Si film 310 is cleaned to remove the remaining dopant. Consequently, the dopant 308 is absorbed into only the region on which the laser beam 309 has been irradiated and the other region is not affected.

In FIG. 3F, photolithographic etching is applied to the quasi-single crystal silicon semiconductor film (qp-Si film) 310 and the p-Si film 307 to etch the films in an island shape, respectively.

In FIG. 3G, an SiO₂ film 311, which changes to a gate insulating layer, is formed on the qp-Si film 310 and the p-Si film 307 etched in an island shape by the plasma CVD method.

In FIG. 3H, a metal layer 312, which changes to a gate wiring and a storage capacitance line, is formed. Photolithographic etching is applied to the metal layer 312 to etch the gate metal layer 312 into the gate wiring and the storage capacitance line.

In FIG. 3I, in order to form a Lightly Doped Drain (LDD) region 330, high concentration P⁺ ions 313 are implanted on the entire surface. Note that, when the LDD structure is not adopted, the high concentration P⁺ ions 313 for manufacturing electrodes are implanted on the entire surface to manufacture source/drain regions 315 with self alignment using gate electrodes.

In FIG. 3J, in order to manufacture source/drain regions of an n-MIS-TFT, the high concentration P⁺ ions 313 are implanted. In this case, the high concentration P⁺ ions 313 are not implanted in a portion that is left as the LDD region 330, using a photoresist 314 as a mask. In this way, the source/drain regions 315 of the n-MIS-TFT are completed (FIG. 3K).

In FIG. 3L, interlayer insulating films 316 are formed. Annealing treatment is performed for activation of the implanted impurities. After etching contact holes 317 by photolithographic etching, source/drain wirings 318 are formed and etched.

In FIG. 3M, a passivation film 319 is formed and terminating treatment is applied to the passivation film 319 to complete the thin film transistors. Consequently, a thin film transistor n-MIS 320 of a single drain structure with a controlled threshold voltage and a thin film transistor n-MIS 321 of an LDD structure, which have different crystal structures and different channels, are completed on the identical substrate 301. The thin film transistor n-MIS 320 using quasi-single crystals is arranged in a drive circuit region DR, and the thin film transistor n-MIS 321 using a polycrystal is arranged in a pixel region AR.

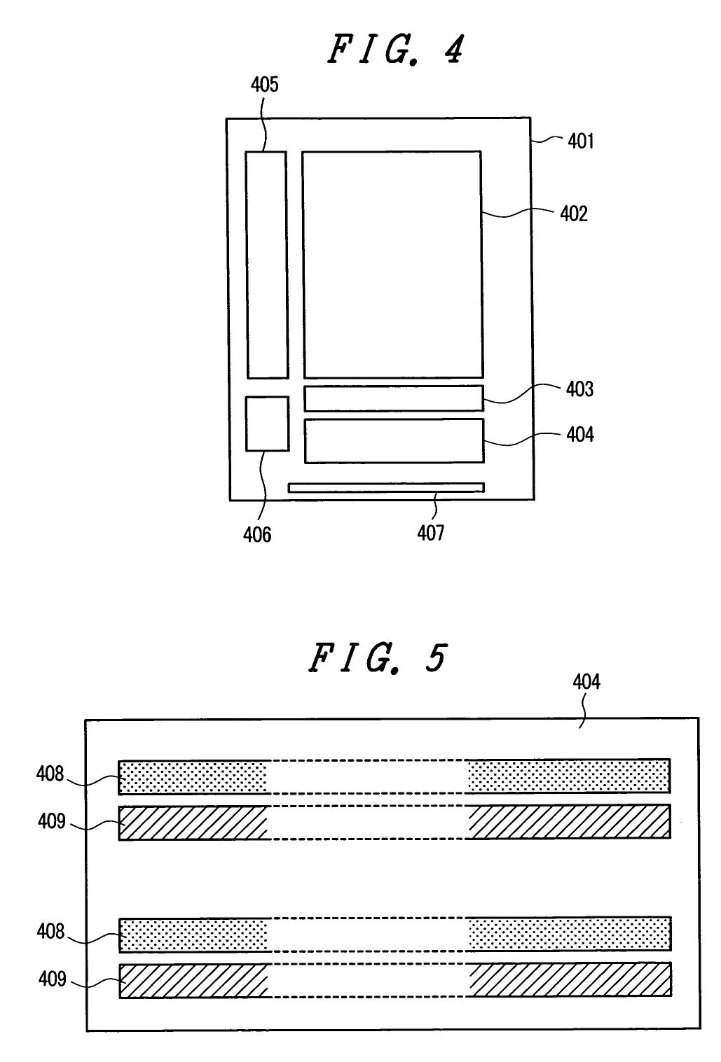

FIG. 4 is a diagram of a thin film transistor substrate constituting the S display device of the present invention. In this thin film transistor substrate (a low-temperature polysilicon TFT substrate), a pixel region 402, peripheral circuits (video signal drive circuits (a signal processing circuit 403 and a horizontal direction scanning circuit 404)), a scanning signal drive circuit (a vertical direction scanning circuit 405), other peripheral circuits 406, such as 10 a booster circuit, and an input pad 407 are arranged on a glass substrate 401.

Thin film transistors using a quasi-single crystal silicon semiconductor in a channel region are formed in the signal processing circuit 403, the horizontal direction scanning circuit 404, and the other peripheral circuits 406 that are required to operate at high speed. Thin film transistors using a polysilicon semiconductor in a channel region are formed in the pixel region 402 and the vertical direction scanning circuit 405 that form other circuit sections. However, the quasi-single crystals may be used in the vertical direction scanning circuit 405 and the pixel region 402. A usual polycrystal may be used in the signal processing circuit 403, the horizontal direction scanning circuit 404, and the other peripheral circuits 406. Note that a thin film transistor using the usual polycrystal and a thin film transistor using the quasi-single crystals may be mixed in one circuit.

FIG. 5 is a diagram showing a layout of thin film transistors that are formed in the circuit sections required to operate at high speed. Here, a horizontal direction scanning circuit 404 is shown as an example. In FIG. 5, an n-MIS thin film transistor has a channel region thereof arranged in a region 408, and a p-MIS thin film transistor has a channel region thereof arranged in a region 409.

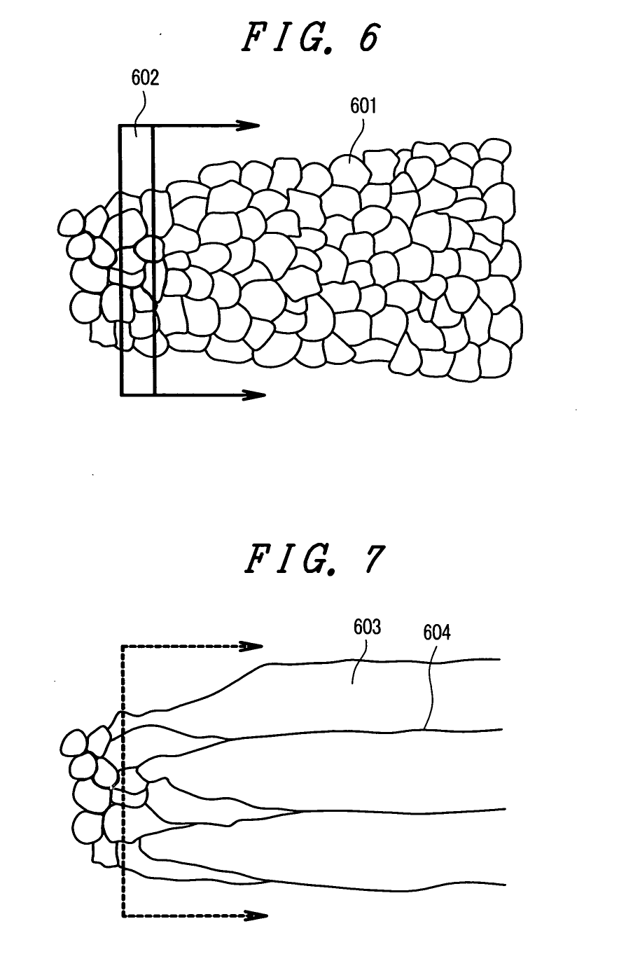

FIG. 6 is a plan view illustrating a quasi-single crystallization technique. A continuous-wave laser beam 602, which is formed in an elongated shape, is used for scanning a semiconductor film 601 in a direction crossing a longitudinal direction (in the figure, a direction indicated by an arrow) while being irradiated. In other words, the continuous-wave laser beam 602 is moved relative to the semiconductor film 601. Note that, for this scanning, the laser beam 602 itself may be moved, the substrate may be moved, or both the laser beam 602 and the substrate may be moved. It is preferable to use a solid-state laser beam as the continuous-wave laser beam 602. In addition, in order to irradiate laser beams on necessary regions selectively, at least one of the pulse width and the pulse interval may be modulated by modulating the intensity of oscillated continuous-wave laser beams, using a modulator, such as an EO modulator.

FIG. 7 is a plan view illustrating a state in which quasi-single crystallization is performed. A fused semiconductor film grows laterally when the semiconductor film solidifies, whereby strip-like crystals (quasi-single crystals) 603 are formed. Reference numeral 604 denotes grain boundaries.

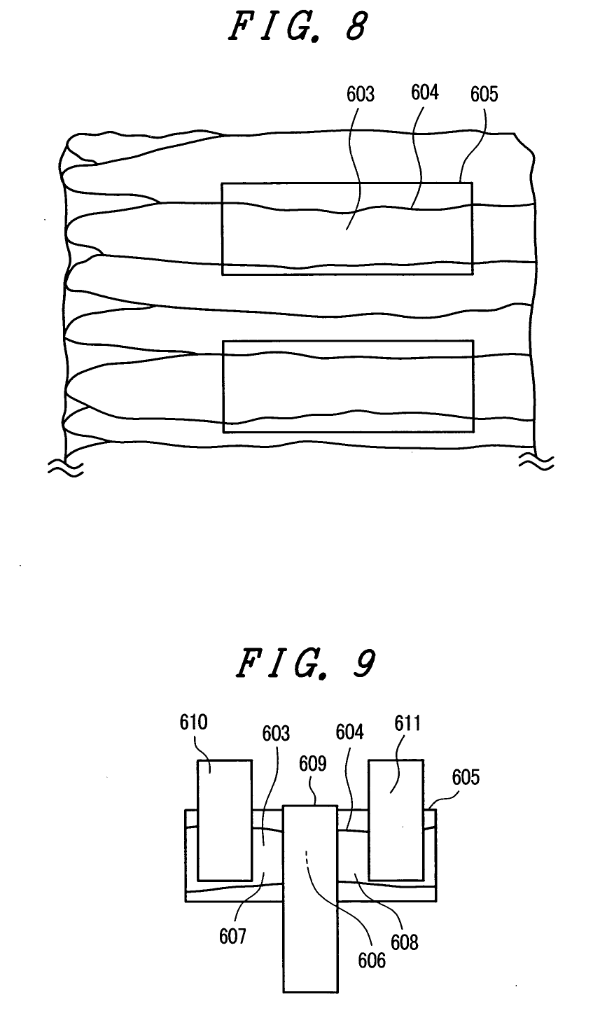

FIG. 8 is a plan view illustrating a state in which quasi-single crystals are etched in an island shape. One or plural island-shaped silicon crystals 605 are patterned in one block-like region subjected to pseudo-single crystallization.

FIG. 9 is a plan view showing an example of a thin film transistor using quasi-single crystals. In the thin-film transistor in this embodiment, after forming a gate electrode 609, impurities are implanted in a source region 607 and a drain region 608. Then, a source electrode 610 and a drain electrode 611 are formed. In a channel region 606, which is disposed immediately below the gate electrode 609, the longitudinal direction of a quasi-single crystal 606 substantially coincides with a direction connecting the source region 607 and the drain region 608, that is, the direction in which an electric current flows. In addition, since the length in the longitudinal direction of the quasi-single crystal is larger than the source-to-drain distance, the grain boundaries 604 hardly prevent the flow of an electric current. Thus, the crystal can be substantially regarded as a single crystal. Therefore, it is possible to attain high electron mobility.

It is possible to apply the invention explained above to various display devices of an active matrix type, such as a liquid crystal display device and an organic EL display device, in the same manner.

The quasi-single crystallization technique in accordance with the invention is not limited to the technique explained with reference to the above-describe embodiments. It is also possible to apply other methods as long as crystallization is performed partially.

Concerning the threshold value control achieved by doping of an impurity in a semiconductor layer in a channel region, in the above-described embodiments, B⁺ ions are used for the n-type thin film transistor and P⁺ ions are used for the p-type thin film transistor. However, the impurity doped in the channel region is irrelevant to determination of a conductivity type of a thin film transistor. Thus, it is also possible for P⁺ ions to be used for the n-type thin film transistor and B⁺ ions to be used for the p-type thin film transistor, as required.

In performing crystallization, even if a thin film is provided between the semiconductor layer and the applied impurities, no problem is caused as long as the film is thin enough for allowing a dopant to be absorbed.

1. A manufacturing method for a display device comprising:
a first thin film transistor that is formed in a first region over a substrate and has a first threshold value according to doping of a first impurity into a semiconductor layer in a channel region; and a second thin film transistor that is formed in a second region over the substrate and has a second threshold value different from the first threshold value according to doping of a second impurity into a semiconductor layer in a channel region, wherein
a crystallized semiconductor layer, which is used in the channel region of the second thin film transistor, is obtained by subjecting a semiconductor layer in the second region to fusing treatment in a state in which the second impurity is applied over the semiconductor layer.

2. A manufacturing method for a display device according to claim 1, wherein a size of a crystal in the semiconductor layer used in the channel region of the second thin film transistor is larger than a size of a crystal in the semiconductor layer used in the channel region of the first thin film transistor.

3. A manufacturing method for a display device according to claim 1, wherein the fusing treatment for the semiconductor layer in the second region is performed by moving a continuous-wave laser relatively to the semiconductor layer while irradiating a laser beam on the semiconductor layer.

4. A manufacturing method for a display device according to claim 1, wherein the semiconductor layer in the first region and the second region is subjected to the fusing treatment to modify the semiconductor layer to a crystallized semiconductor layer before applying the second impurity to the semiconductor layer.

5. A manufacturing method for a display device according to claim 1, wherein a conductivity type of the first thin film transistor and a conductivity type of the second thin film transistor are the same.

6. A manufacturing method for a display device according to claim 1, wherein a conductivity type of the first thin film transistor and a conductivity type of the second thin film transistor are different.

7. A manufacturing method for a display device comprising:
a first thin film transistor that is formed in a first region over a substrate and has a first threshold value according to doping of a first impurity into a semiconductor layer in a channel region; and a second thin film transistor that is formed in a second region over the substrate and has a second threshold value different from the first threshold value according to doping of a second impurity into a semiconductor layer in a channel region, wherein
a crystallized semiconductor layer, which is used in the channel region of the first thin film transistor, is obtained by subjecting a semiconductor layer in the first region to fusing treatment in a state in which the first impurity is applied over the semiconductor layer, and
a crystallized semiconductor layer, which is used in the channel region of the second thin film transistor, is obtained by subjecting a semiconductor layer in the second region to fusing treatment in a state in which the second impurity is applied over the semiconductor layer.

8. A manufacturing method for a display device according to claim 7, wherein the semiconductor layer of the first thin film transistor and the semiconductor layer of the second thin film transistor have strip-like crystals.

9. A manufacturing method for a display device according to claim 7, wherein the fusing treatment for the semiconductor layer in the first region and the fusing treatment for the semiconductor layer in the second region are performed by moving a continuous-wave laser relatively to the semiconductor layer while irradiating laser beam on the semiconductor layer.

10. A manufacturing method for a display device according to claim 7, wherein a conductivity type of the first thin film transistor and a conductivity type of the second thin film transistor are the same.

11. A manufacturing method for a display device according to claim 7, wherein a conductivity type of the first thin film transistor and a conductivity type of the second thin film transistor are different.

12. A manufacturing method for a display device comprising:
a first thin film transistor that is formed in a first region over a substrate and has a first threshold value according to doping of a first impurity into a semiconductor layer in a channel region; and a second thin film transistor that is formed in a second region over the substrate and has a second threshold value different from the first threshold value according to doping of a second impurity into a semiconductor layer in a channel region, wherein
a crystallized semiconductor layer, which is used in the channel region of the first thin film transistor, is obtained by subjecting a semiconductor layer in the first region and the second region to fusing treatment in a state in which the first impurity is applied over the semiconductor layer, and
a crystallized semiconductor layer, which is used in the channel region of the second thin film transistor, is obtained by subjecting the semiconductor layer in the second region to fusing treatment in a state in which the second impurity is applied over the semiconductor layer.

13. A manufacturing method for a display device according to claim 12, wherein a size of a crystal in the semiconductor layer used in the channel region of the second thin film transistor is larger than a size of a crystal in the semiconductor layer used in the channel region of the first thin film transistor.

14. A manufacturing method for a display device according to claim 12, wherein the fusing treatment for the semiconductor layer in the second region is performed by moving a continuous-wave laser relatively to the semiconductor layer while irradiating a laser beam on the semiconductor layer.

15. A manufacturing method for a display device according to claim 12, wherein the fusing treatment for the semiconductor layer in the first region and the second region in a state in which the first impurity is applied over the semiconductor layer is performed by irradiating an excimer laser beam or a solid-state laser beam on the semiconductor layer.

16. A manufacturing method for a display device according to claim 12, wherein a conductivity type of the first thin film transistor and a conductivity type of the second thin film transistor are the same.

17. A manufacturing method for a display device according to claim 12, wherein a conductivity type of the first thin film transistor and a conductivity type of the second thin film transistor are different.
